(19) United States
(12) Patent Application Publication
(10) Pub. No.: US 2017/0370988 A1
(43) Pub. Date: Dec. 28, 2017

(54) BURN-IN TESTING OF INDIVIDUALLY PERSONALIZED SEMICONDUCTOR DEVICE CONFIGURATION

(71) Applicant: INTERNATIONAL BUSINESS MACHINES CORPORATION, ARMONK, NY (US)

(72) Inventors: Franco Motika, Hopewell Junction, NY (US); Soungbum You, Poughkeepsie, NY (US)

(21) Appl. No.: 15/194,971

(22) Filed: Jun. 28, 2016

(51) Int. Cl. G01R 31/28

(52) U.S. Cl. CPC G01R 31/2874

(57) ABSTRACT

Examples of techniques for burn-in testing of an individually personalized device configuration are disclosed. In one example implementation according to aspects of the present disclosure, a computer-implemented method may include: retrieving the individually personalized device configuration; enabling a device to receive the individually personalized device configuration, wherein the device is one of a plurality of devices; and loading the individually personalized device configuration to the device that is enabled, wherein other devices of the plurality of devices are disabled from receiving the individually personalized device configuration.

### BACKGROUND

The present disclosure relates to burn-in techniques for testing semiconductor devices and, more particularly, to burn-in testing of individually personalized semiconductor device configurations.

A typical technique for stressing semiconductor devices in a burn-in environment is to load multiple devices on a burn-in-board (BIB) and insert the BIB in a temperature controlled oven. These devices are usually the same design and are electrically bussed in parallel on the BIB. This allows for a single test system to load and initiate the same switching exercises on all devices concurrently. This device internal switching activity in conjunction with power supply pulsing and temperature cycling is used to accelerate early device failure modes and improve the overall product long term reliability.

### SUMMARY

According to examples of the present disclose, techniques including methods, systems, and/or computer program products for burn-in testing of an individually personalized device configuration are provided. An example method may include: retrieving the individually personalized device configuration; enabling a device to receive the individually personalized device configuration, wherein the device is one of a plurality of devices; and loading the individually personalized device configuration to the device that is enabled, wherein other devices of the plurality of devices are disabled from receiving the individually personalized device configuration.

Additional features and advantages are realized through the techniques of the present disclosure. Other aspects are described in detail herein and are considered a part of the disclosure. For a better understanding of the present disclosure with the advantages and the features, refer to the following description and to the drawings.

### BRIEF DESCRIPTION OF THE DRAWINGS

The subject matter which is regarded as the invention is particularly pointed out and distinctly claimed in the claims at the conclusion of the specification. The foregoing and other features, and advantages thereof, are apparent from the following detailed description taken in conjunction with the accompanying drawings in which:

FIG. 1 illustrates a block diagram of a burn-in system for testing devices under test using burn-in boards according to examples of the present disclosure;

FIG. 2 illustrates a block diagram of a burn-in system for testing devices under test using burn-in boards according to examples of the present disclosure;

FIG. 3 illustrates a block diagram of a burn-in system for testing devices under test using burn-in boards according to examples of the present disclosure;

FIG. 4 illustrates a block diagram of a burn-in system for testing devices under test using burn-in boards according to examples of the present disclosure;

FIG. 5 illustrates a flow diagram of a method 500 for burn-in testing of an individually personalized device configuration according to examples of the present disclosure; and

FIG. 6 illustrates a block diagram of a processing system for implementing the techniques described herein according to examples of the present disclosure.

### DETAILED DESCRIPTION

Present burn-in techniques have proven effective in the past, but these techniques encounter a significant problem when testing devices that provide individual personalization. For instance, individually personalized devices pose particular problems during testing due to their individual repairability and partial good configuration. This is especially true when the device design incorporates very large numbers of a particular macro that requires customized repairs such as memory array macros. The basic problem is that in order to load specific repair actions or to custom configure each device with unique internal setups, each device needs to be addressed individually on the BIB. A lack of observability of the device during burn-in and the acquisition of the failing information for each individual device pose additional problems.

As very-large-scale integration (VLSI) semiconductor devices increase in density, the size of integrated memory arrays (SRAMs & DRAMs) require large repair to achieve reasonable yields. Furthermore, the partial good methodology has also been increasing and requires similar device internal setup configuration to exclude defective cores or enable redundant macros.

Complex system-on-a-chip (SOC) devices utilize additional on-chip support to individually reconfigure the chip using, for example, power fencing, clock gating, reconfigurable data paths, and/or bypassing defective memory and logic, during the burn-in process. Further, reconfiguring and isolating other regions of complex multi-core or SOC designs are useful for effective burn-in stress of good and partially good devices.

The present disclosure provides for a unique device specific configuration technique applicable to multiple devices bussed in parallel on a BIB during concurrent thermal and electrical switching stress testing. The disclosed techniques enable an individual, highly effective methodology for stressing repairable and partial good devices. The concept is further enhanced by design-for-test (DFT) extensions to support the burn-in stress features.

Various implementations are described below by referring to several examples of burn-in testing of individually personalized semiconductor device configurations. The present techniques enable individual access from a test system to the devices-under-test (DUTs) on a burn-in board in a burn-in environment. Each of the DUTs can be personalized with a specific configuration to enable a stress test (e.g., concurrent thermal and electrical switching stress testing) of desired circuits while selectively disabling non-functional, redundant circuits from being tested. Additionally, each DUT can be monitored and dynamically re-configured during tests. The present techniques provide for stress testing repairable and partially good DUTs. The present techniques may utilize design-for-test (DFT) extensions to support a burn-in stress system.

In examples, the present disclosure provides for utilizing a serial device interface to control the enabling and disabling of the parallel bussing structure of multiple devices under test on a burn-in board during stress testing. The loading of individually personalized device configuration data for each of the DUTs on the burn-in board is useful for an effective burn-in methodology. Once these personalization data have been loaded onto a DUT, the setup is preserved for the duration of that portion of the stress test switching activity.

To realize this personalization in a parallel device busing structure, it is useful to disable all but the device (or devices) being loaded with the individually personalized device configuration data. Similarly, the same device selection capability is used to retrieving the results from the DUT after the stress test is complete. This device addressing capability can be achieved by wiring the field replaceable unit (FRU) service interface (FSI) ports for each DUT and then using this serial port to enable or disable the selected device parallel port, for example. Many high-end VLSI and SOC devices have an existing serial port used in a system for maintenance and diagnostic access.

In some implementations, the present techniques improve device quality and reliability by effectively stressing functionally reconfigured devices. The present techniques also increase final device yield by not stressing and failing unused circuits. Moreover, the present techniques provide for in situ monitoring and diagnostic enablement of failing devices while being tested. These and other advantages will be apparent from the description that follows.

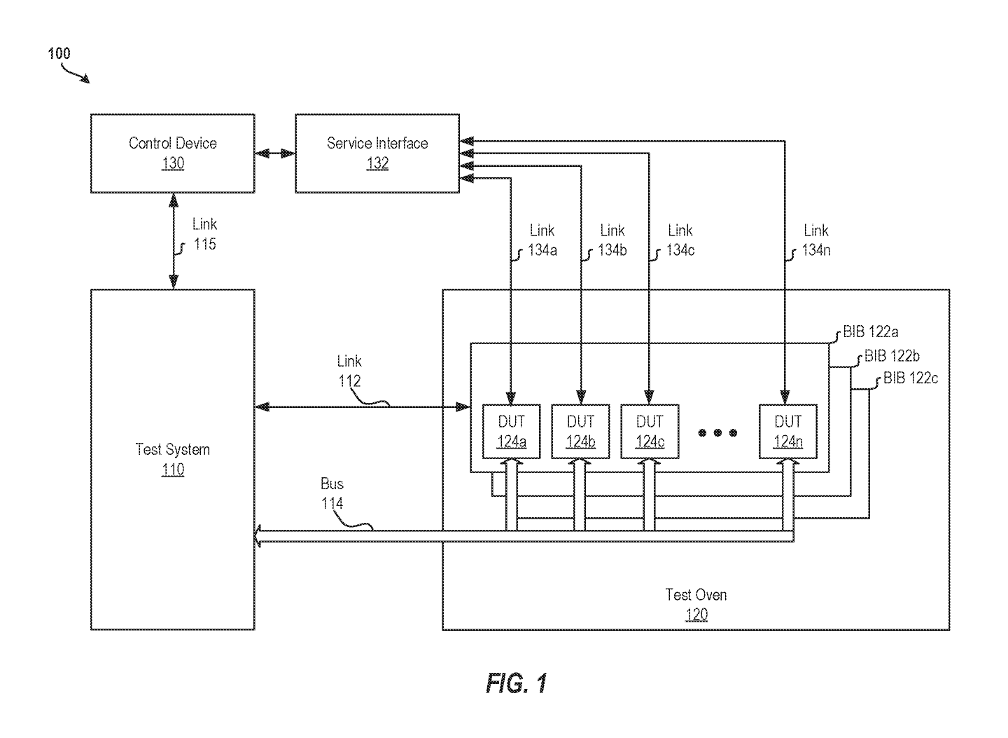

FIG. 1 illustrates a block diagram of a burn-in system 100 for testing devices under test (DUTs) 124a, 124b, 124c, 124n using burn-in boards 122a, 122b, 122c according to examples of the present disclosure. In particular, the burn-in system 100 provides for burn-in testing of individually personalized semiconductor device configuration. The DUTs 124a-124n represent semiconductor devices to be tested by the test system 110.

The burn-in system 100 includes a test system 110, a test oven 120, a control device 130, and a service interface 132. DUTs 124a, 124b, 124c, 124n are connected to the burn-in boards 122a, 122b, 122c, which are contained within the test oven 120.

The test system 110 may represent a traditional burn-in test system. This enables testing of DUTs 124a, 124b, 124c, 124n without modifying the DUTs 124a, 124b, 124c, 124n. The test system 110 is responsible for device setup, test sequencing, pattern loading, chip select via Link 115, individual repair loading, pattern execution, and/or results procurement, etc. The test oven 120 provides a test environment that enables stress testing of the DUTs 124a, 124b, 124c, 124n.

In the present example, an individually personalized device configuration may be loaded to a selected one (or more) of the DUTs 124a, 124b, 124c, 124n using emulated patterns applied to the selected DUT via FSI port on the selected DUT via the control interface 130 and the service interface 132. In particular, the control interface 130 provides a designer application tool to design the individually personalized device configurations and designate the DUTs to which the configurations are to be loaded.

The control interface 130 sends a signal to the service interface 132 to indicate which of the DUTs is selected to receive the individually personalized device configuration. The service interface 132 enables the selected DUT via the FSI port on the selected DUT via the link 134a-134n corresponding with the selected DUT 124a-124n.

The execution pattern is modified or “poked” with personalized data prior to execution via the bus 114 between the test system 110 and the BIBs 122a-c. The execution pattern poking may be repeated for each DUT 124a, 124b, 124c, 124n as desired. Once the personalization of the desired DUTs 124a-124n is complete, execution of the stress switching pattern can be initiated via the link 112.

It should be appreciated that the examples disclosed herein may support dynamic monitoring and reconfiguration of devices during in-situ burn-in stress. This may be beneficial when a particular DUT maintains its own internal pattern execution (e.g., logic built-in self-test (LBIST), array built-in self-test (ABIST), etc.). Additionally, the switching execution can be controlled or staggered between DUTs to minimize power requirements or noise associated issues. It should also be appreciated that, although multiple burn-in boards are illustrated, single burn-in board implementations are also possible.

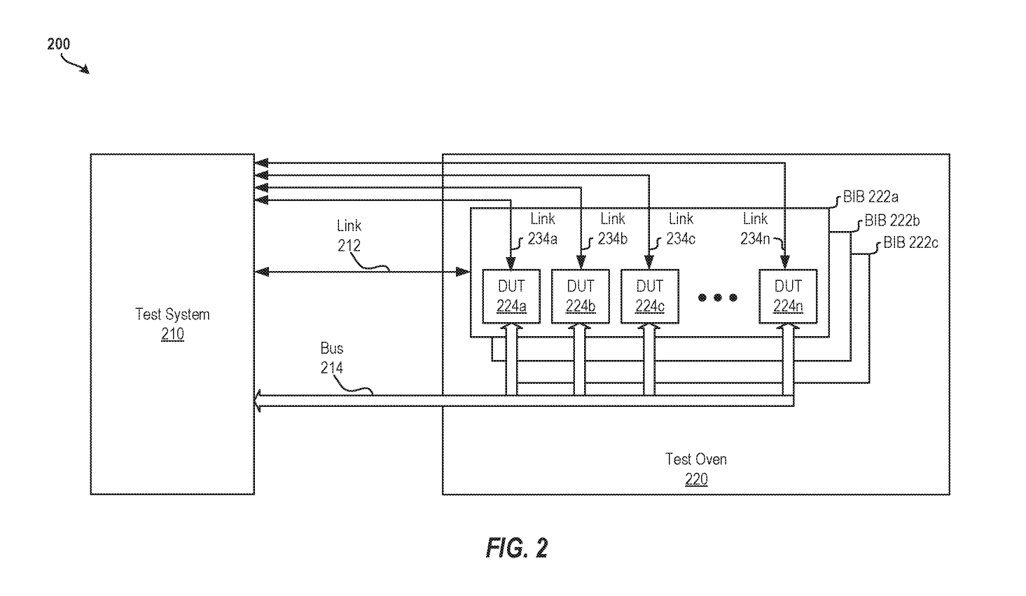

FIG. 2 illustrates a block diagram of a burn-in system 200 for testing devices under test (DUTs) 224a, 224b, 224c, 224n using burn-in boards 222a, 222b, 222c according to examples of the present disclosure. The burn-in system 200 includes a test system 210 and a test oven 220. DUTs 224a, 224b, 224c, 224n are connected to the burn-in boards 222a, 222b, 222c, which are contained within a test oven 220.

In the example of FIG. 2, the links 234a, 234b, 234c, 234n connect directly between the test system 210 and the DUTs 224a, 224b, 224c, 224n respectively. The links 234a, 234b, 234c, 234n may be, for example, parallel interface links, serial interface links, radio frequency links, or other appropriate communication links.

In some examples, the links 234a, 234b, 234c, 234n send a signal to select the respective DUTs 224a, 224b, 224c, 224n to enable and disable the DUTs access by the bus 214. Moreover, the links 234a, 234b, 234c, 234n may send the individually personalized device configuration to the DUTs 224a, 224b, 224c, 224n (whichever is/are enabled). However, in other examples, the bus 214 may be used to send the individually personalized device configuration to the DUTs 224a, 224b, 224c, 224n (whichever is/are enabled).

The test system 210 is responsible for device setup, test sequencing, pattern loading, chip select, individual repair loading, pattern execution, and/or results procurement, etc.

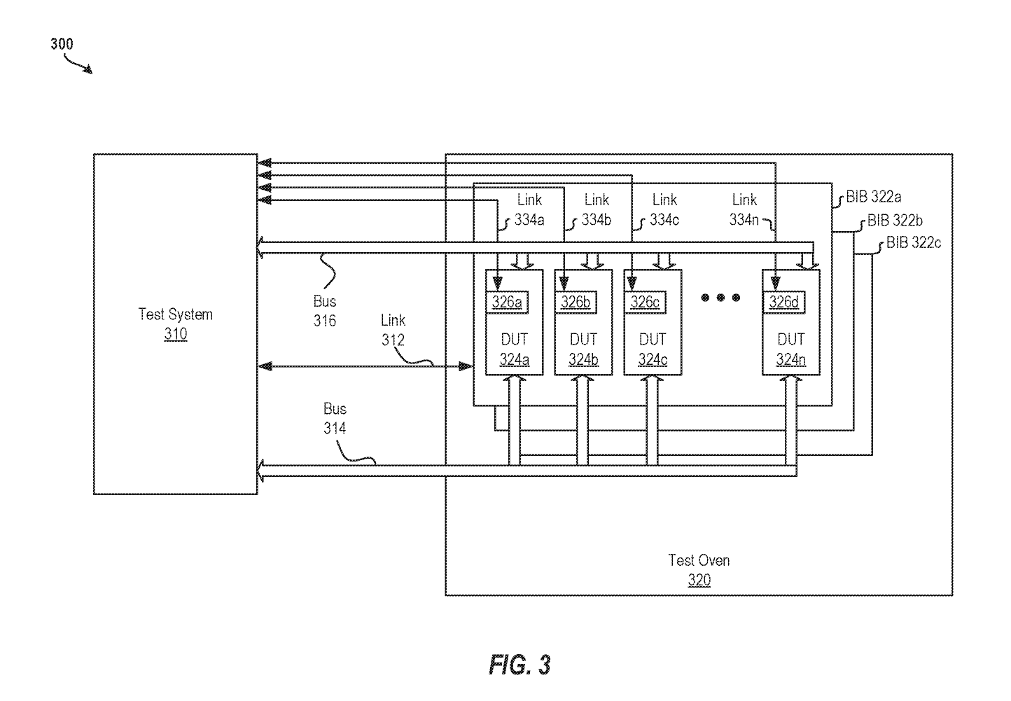

FIG. 3 illustrates a block diagram of a burn-in system 300 for testing devices under test (DUTs) 324a, 324b, 324c, 324n using burn-in boards 322a, 322b, 322c according to examples of the present disclosure. The burn-in system 300 includes a test system 310 and a test oven 320. DUTs 324a, 324b, 324c, 324n are connected to the burn-in boards 322a, 322b, 322c, which are contained within a test oven 320.

In particular, the example illustrated in FIG. 3 is based on on-chip design for test (DFT) to support enabling and disabling the DUT parallel ports, the bus 314 and bus 316, via a control port 326a, 326b, 326c, 326n on each respective DUT 324a, 324b, 324c, 324n. In this case, a latch is loaded via the control port 326a, 326b, 326c, 326n on each DUT 324a, 324b, 324c, 324n to either enable (select) or disable the respective DUT.

It should be appreciated that each of the DUTs 324a, 324b, 324c, 324n includes multiple individual busses for device configuration and pattern execution. This approach enables more efficient device setup via the parallel bus and broader test methodology execution features.

In the example of FIG. 3, the links 334a, 334b, 334c, 334n provide individual connections to the control ports 326a, 326b, 326c, 326n for each of the DUTs 324a, 324b, 324c, 324n. This enables each of the DUTs 324a, 324b, 324c, 324n busses 314 and 316, to be individually enabled and disabled by the test system 310. The test system 310 provides configuration information to each of the DUTs 324a, 324b, 324c, 324n via bus 316 and pattern data via the bus 314.

The test system 310 is responsible for device setup, test sequencing, pattern loading, chip select, individual repair loading, pattern execution, individual DUT enabling/disabling, and/or results procurement, etc.

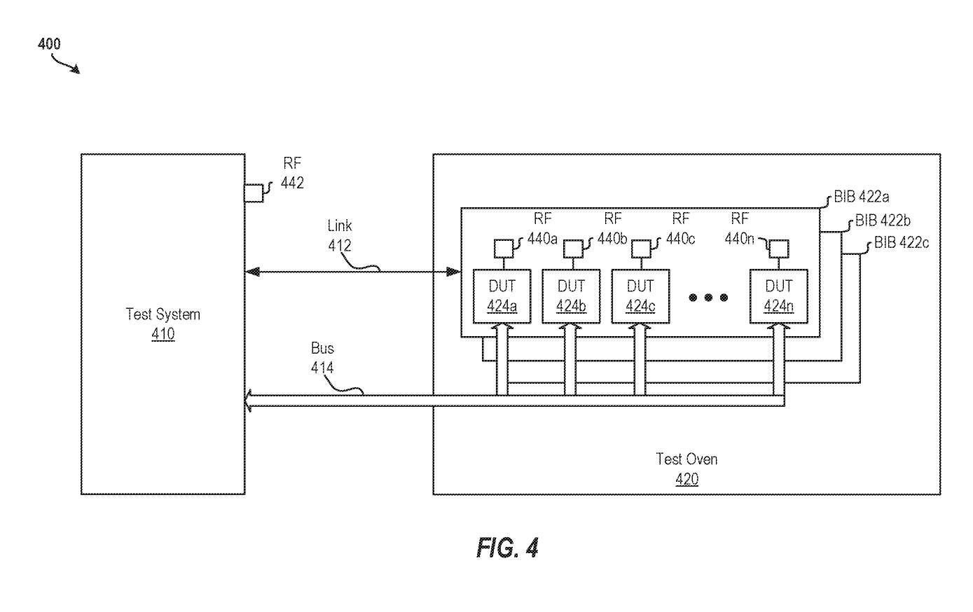

FIG. 4 illustrates a block diagram of a burn-in system 400 for testing devices under test (DUTs) 424a, 424b, 424c, 424n using burn-in boards 422a, 422b, 422c according to examples of the present disclosure. The burn-in system 400 includes a test system 410 and a test oven 420. DUTs 424a, 424b, 424c, 424n are connected to the burn-in boards 422a, 422b, 422c, which are contained within a test oven 420.

In the present example, the test system 410 comprises a radio frequency (RF) transceiver 442, and each of the DUTs 424a, 424b, 424c, 424n includes an RF transceiver 440a, 440b, 440c, 440n respectively. An RF link may be established between each the RF transceiver 442 and each of the RF transceivers 440a, 440b, 440c, 440n. This enables the test system 410 to enable and disable each of the DUTs 424a, 424b, 424c, 424n via the RF link. It should be appreciated that, according to aspects of the present disclosure, the RF link can be extended to replace the link 412 and/or the bus 414. It should also be appreciated that other wireless communication techniques may be used instead of, in addition to, or in conjunction with radio frequency. For example, Bluetooth, Wi-Fi, infrared and/or visible light communication, mesh networking, and/or other wireless communication techniques.

The test system 410 is responsible for device setup, test sequencing, initializing the devices under test, pattern loading, radio frequency DUT socket selection, individual repair loading, pattern execution, individual DUT enabling/disabling via radio frequency, individual DUT access, and/or results procurement, etc.

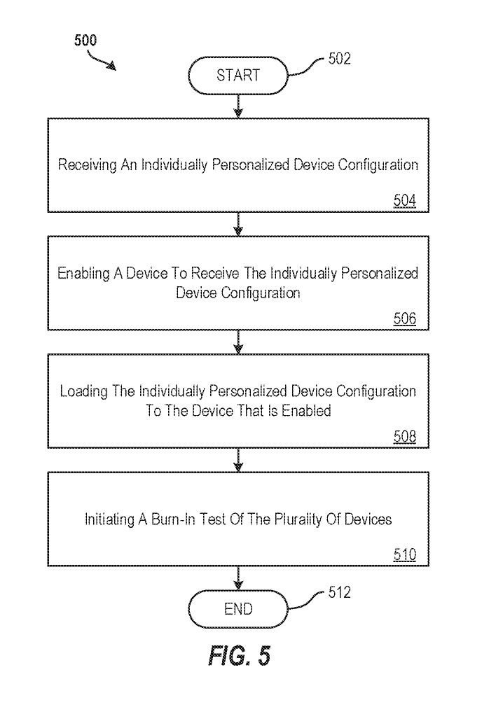

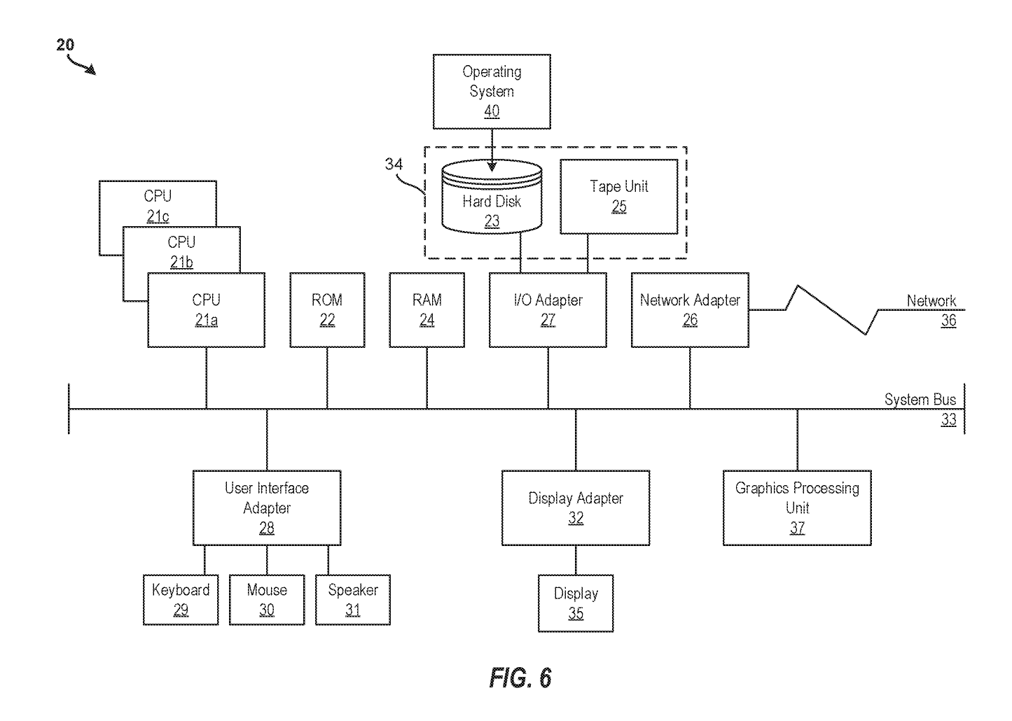

FIG. 5 illustrates a flow diagram of a method 500 for burn-in testing of an individually personalized device configuration according to examples of the present disclosure. The method 500 may be performed, for example, by the processing system 20 of FIG. 6, described below, or by another suitable processing system. The method 500 starts at block 502 and continues to block 504.

At block 504, the method 500 includes retrieving the individually personalized device configuration. In examples, the personalized device configuration may be generated prior to being retrieved by a wafer test, module test, or some other suitable test.

At block 506, the method 500 includes enabling a device (e.g., DUT 124a of FIG. 1) to receive the individually personalized device configuration. The device is one of a plurality of devices, for example, devices under test connected to a burn-in board (e.g., BIB 122a of FIG. 1). The device may be enabled (and subsequently disabled) in a number of ways as discussed above. For example, the device may be enabled via a serial interface, a parallel interface, a radio frequency interface, or another suitable communication interface between the burn-in test system (e.g., the test system 110 of FIG. 1) and the device. In another example, the device is enabled via a field-replaceable unit service interface between a control device (e.g., control device 130 of FIG. 1) and the device.

At block 508, the method 500 includes loading the individually personalized device configuration to the device that is enabled. Other devices of the plurality of devices (i.e., not the enabled device) are disabled from receiving the individually personalized device configuration. This enables only the device for which the individually personalized device configuration was generated to receive the individually personalized device configuration.

At block 510, the method 500 includes initiating a burn-in test of the plurality of devices. According to aspects of the present disclosure, the plurality of devices are connected to a burn-in board for testing the plurality of devices. The burn-in board and the plurality of devices are positioned within an oven to provide heat to the plurality of devices. The testing may be performed by a burn-in test system (e.g., the test system 110 of FIG. 1). The method 500 continues to block 512 and ends.

Additional processes also may be included. For example, it may be desirable to upload different individually personalized device configurations to multiple devices. In such cases, where the device referenced above is the first device, the method 500 may include, subsequent to loading the individually personalized device configuration to the first device, disabling the first device. The method 500 may further include generating a second individually personalized device configuration. Further, the method may include enabling a second device to receive the second individually personalized device configuration, wherein the second device is one of the plurality of devices, and wherein other devices of the plurality of devices and the first device are disabled from receiving the second individually personalized device configuration. The method 500 may also include loading the second individually personalized device configuration to the device, and initiating a burn-in test of the plurality of devices.

In another example, the method 500 may include, subsequent to loading the individually personalized device configuration to the device, disabling the device. The method 500 may further include enabling the plurality of devices not including the first device. The method 500 may then include loading a standard device configuration to the plurality of devices not including the first device, and initiating a burn-in test of the plurality of devices.

It should be understood that the processes depicted in FIG. 5 represent illustrations, and that other processes may be added or existing processes may be removed, modified, or rearranged without departing from the scope and spirit of the present disclosure.

It is understood in advance that the present disclosure is capable of being implemented in conjunction with any other type of computing environment now known or later developed. For example, FIG. 6 illustrates a block diagram of a processing system 20 for implementing the techniques described herein. In examples, processing system 20 has one or more central processing units (processors) 21a, 21b, 21c, etc. (collectively or generically referred to as processor(s) 21 and/or as processing device(s)). In aspects of the present disclosure, each processor 21 may include a reduced instruction set computer (RISC) microprocessor. Processors 21 are coupled to system memory (e.g., random access memory (RAM) 24) and various other components via a system bus 33. Read only memory (ROM) 22 is coupled to system bus 33 and may include a basic input/output system (BIOS), which controls certain basic functions of processing system 20.

Further illustrated are an input/output (I/O) adapter 27 and a communications adapter 26 coupled to system bus 33. I/O adapter 27 may be a small computer system interface (SCSI) adapter that communicates with a hard disk 23 and/or a tape storage drive 25 or any other similar component. I/O adapter 27, hard disk 23, and tape storage device 25 are collectively referred to herein as mass storage 34. Operating system 40 for execution on processing system 20 may be stored in mass storage 34. A network adapter 26 interconnects system bus 33 with an outside network 36 enabling processing system 20 to communicate with other such systems.

A display (e.g., a display monitor) 35 is connected to system bus 33 by display adaptor 32, which may include a graphics adapter to improve the performance of graphics intensive applications and a video controller. In one aspect of the present disclosure, adapters 26, 27, and/or 32 may be connected to one or more I/O busses that are connected to system bus 33 via an intermediate bus bridge (not shown). Suitable I/O buses for connecting peripheral devices such as hard disk controllers, network adapters, and graphics adapters typically include common protocols, such as the Peripheral Component Interconnect (PCI). Additional input/output devices are shown as connected to system bus 33 via user interface adapter 28 and display adapter 32. A keyboard 29, mouse 30, and speaker 31 may be interconnected to system bus 33 via user interface adapter 28, which may include, for example, a Super I/O chip integrating multiple device adapters into a single integrated circuit.

In some aspects of the present disclosure, processing system 20 includes a graphics processing unit 37. Graphics processing unit 37 is a specialized electronic circuit designed to manipulate and alter memory to accelerate the creation of images in a frame buffer intended for output to a display. In general, graphics processing unit 37 is very efficient at manipulating computer graphics and image processing, and has a highly parallel structure that makes it more effective than general-purpose CPUs for algorithms where processing of large blocks of data is done in parallel.

Thus, as configured herein, processing system 20 includes processing capability in the form of processors 21, storage capability including system memory (e.g., RAM 24), and mass storage 34, input means such as keyboard 29 and mouse 30, and output capability including speaker 31 and display 35. In some aspects of the present disclosure, a portion of system memory (e.g., RAM 24) and mass storage 34 collectively store an operating system such as the AIX® operating system from IBM Corporation to coordinate the functions of the various components shown in processing system 20.

The present techniques may be implemented as a system, a method, and/or a computer program product. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some examples, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to aspects of the present disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the figures illustrate the architecture, functionality, and operation of possible implementations of systems, methods, and computer program products according to various aspects of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various examples of the present disclosure have been presented for purposes of illustration, but are not intended to be exhaustive or limited to the embodiments disclosed. Many modifications and variations will be apparent to those of ordinary skill in the art without departing from the scope and spirit of the described techniques. The terminology used herein was chosen to best explain the principles of the present techniques, the practical application or technical improvement over technologies found in the marketplace, or to enable others of ordinary skill in the art to understand the techniques disclosed herein.

What is claimed is:

1. A computer-implemented method for burn-in testing of an individually personalized device configuration, the method comprising:
retrieving the individually personalized device configuration;
enabling a device to receive the individually personalized device configuration, wherein the device is one of a plurality of devices; and
loading the individually personalized device configuration to the device that is enabled, wherein other devices of the plurality of devices are disabled from receiving the individually personalized device configuration.

2. The computer-implemented method of claim 1, further comprising:
initiating a burn-in test of the plurality of devices.

3. The computer-implemented method of claim 1, wherein the device is a first device, the method further comprising:
subsequent to loading the individually personalized device configuration to the first device, disabling the first device;
retrieving a second individually personalized device configuration;
enabling a second device to receive the second individually personalized device configuration, wherein the second device is one of the plurality of devices, and wherein other devices of the plurality of devices and the first device are disabled from receiving the second individually personalized device configuration;
loading the second individually personalized device configuration to the device; and
initiating a burn-in test of the plurality of devices.

4. The computer-implemented method of claim 1, wherein the device is enabled via a serial interface between a burn-in test system and the device.

5. The computer-implemented method of claim 1, wherein the device is enabled via a parallel interface between a burn-in test system and the device.

6. The computer-implemented method of claim 1, wherein the device is enabled via a field-replaceable unit service interface between a control device and the device.

7. The computer-implemented method of claim 1, wherein the device is enabled via a radio frequency interface between a burn-in test system and the device.

8. The computer-implemented method of claim 1, wherein the plurality of devices are connected to a burn-in board for testing the plurality of devices, and wherein the burn-in board and the plurality of devices are positioned within an oven to provide heat to the plurality of devices.

9. The computer-implemented method of claim 1, further comprising:
subsequent to loading the individually personalized device configuration to the device, disabling the device;
enabling the plurality of devices not including the device;
loading a standard device configuration to the plurality of devices not including the device; and
initiating a burn-in test of the plurality of devices.

10. A system for burn-in testing of an individually personalized device configuration, the system comprising:
a memory having computer readable instructions; and
a processing device for executing the computer readable instructions, the computer readable instructions comprising:
retrieving the individually personalized device configuration;
enabling a device to receive the individually personalized device configuration, wherein the device is one of a plurality of devices; and
loading the individually personalized device configuration to the device that is enabled, wherein other devices of the plurality of devices are disabled from receiving the individually personalized device configuration.

11. The system of claim 10, wherein the computer readable instructions further comprise:
initiating a burn-in test of the plurality of devices.

12. The system of claim 10, wherein the device is a first device, and wherein the computer readable instructions further comprise:
subsequent to loading the individually personalized device configuration to the first device, disabling the first device;
retrieving a second individually personalized device configuration;
enabling a second device to receive the second individually personalized device configuration, wherein the second device is one of the plurality of devices, and wherein other devices of the plurality of devices and the first device are disabled from receiving the second individually personalized device configuration;
loading the second individually personalized device configuration to the device; and
initiating a burn-in test of the plurality of devices.

13. The system of claim 10, wherein the device is enabled via a serial interface between a burn-in test system and the device.

14. The system of claim 10, wherein the device is enabled via a parallel interface between a burn-in test system and the device.

15. The system of claim 10, wherein the device is enabled via a field-replaceable unit service interface between a control device and the device.

16. The system of claim 10, wherein the device is enabled via a radio frequency interface between a burn-in test system and the device.

17. The system of claim 10, wherein the plurality of devices are connected to a burn-in board for testing the plurality of devices, and wherein the burn-in board and the plurality of devices are positioned within an oven to provide heat to the plurality of devices.

18. The system of claim 10, further comprising:
subsequent to loading the individually personalized device configuration to the device, disabling the device;
enabling the plurality of devices not including the device;
loading a standard device configuration to the plurality of devices not including the device; and
initiating a burn-in test of the plurality of devices.

19. A computer program product for burn-in testing of an individually personalized device configuration, the computer program product comprising:
a non-transitory computer readable storage medium having program instructions embodied therewith, the program instructions executable by a processing device to cause the processing device to:
retrieve the individually personalized device configuration;
enable a device to receive the individually personalized device configuration, wherein the device is one of a plurality of devices; and
load the individually personalized device configuration to the device that is enabled, wherein other devices of the plurality of devices are disabled from receiving the individually personalized device configuration.

20. The computer program product of claim 19, wherein the program instructions cause the processing device to:
subsequent to loading the individually personalized device configuration to the device, disable the device;
enable the plurality of devices not including the device;
load a standard device configuration to the plurality of devices not including the device; and
initiate a burn-in test of the plurality of devices.
